(19) United States
(12) Patent Application Publication
(10) Pub. No.: US 2024/0250205 A1
(43) Pub. Date: Jul. 25, 2024

(54) MICRO-LED DEVICE AND METHOD FOR FABRICATING SAME

(71) Applicant: TCL China Star Optoelectronics Technology Co., Ltd., Shenzhen (CN)

(72) Inventor: Wanchun WU, Shenzhen (CN)

(21) Appl. No.: 17/610,512

(22) PCT Filed: Sep. 17, 2021
(86) PCT No.: PCT/CN2021/118960

§ 371 Date: Nov. 11, 2021

(30) Foreign Application Priority Data
Sep. 13, 2021 (CN) 202111068902.5

(51) Int. Cl. H01L 33/00; H01L 33/62

(52) U.S. Cl. CPC H01L 33/0093; H01L 33/62

(57) ABSTRACT

A micro-light emitting diode (micro-LED) device and a method for fabricating the same are provided. The method includes: providing an imprinting mold; coating a photoresist solution on a side surface of a substrate to form a liquid photoresist layer which is uncured; pressing first protrusions of the imprinting mold onto the liquid photoresist layer; curing the liquid photoresist layer to form a solid photoresist layer; removing the imprinting mold from the solid photoresist layer to obtain the solid photoresist layer which is patterned, wherein the solid photoresist layer includes a plurality of second protrusions and openings; forming a metal layer on upper surfaces of the second protrusions and in the openings; and peeling off the second protrusions and parts of the metal layer formed on the upper surfaces of the second protrusions to form a metal circuit.

### FIELD OF INVENTION

The present disclosure relates to the technical field of display, and particularly to a micro-light emitting diode (micro-LED) device and a method for fabricating the same.

### BACKGROUND

Micro-light emitting diodes (micro-LEDs) refer to LEDs with a size less than 100 μm. High-density display devices composed of the micro-LEDs have advantages of high brightness, high contrast, and high resolution, and have become one of the focuses in the display field.

In a current commonly used micro-LED device, a circuit manufacturing process of the micro-LED device generally first performs laser engraving on a front surface to form a front circuit, and then performs laser engraving on a side surface to form a side circuit. Specifically, in a process of forming the front circuit or the side circuit, a silver paste is first coated on a surface of a substrate, then the silver paste is cured by laser, and finally the cured silver paste is laser engraved to form the front circuit or the side circuit.

Therefore, the micro-LED device requires two laser engravings to form the front circuit and the side circuit. However, because the laser engravings are complicated, a tact time is long.

### SUMMARY OF DISCLOSURE

A purpose of the present disclosure is to provide a micro-light emitting diode (micro-LED) device and a method for fabricating the same, so as to solve a technical problem that laser engraving a side circuit of a current micro-LED device is complicated and causes a long tact time.

In order to achieve the above purpose, the present disclosure provides a method for fabricating a micro-light emitting diode (micro-LED) device, which comprises: providing an imprinting mold, wherein a side surface of the imprinting mold has a plurality of first protrusions arranged in an array; coating a photoresist solution on a side surface of a substrate to form a liquid photoresist layer which is uncured; pressing the first protrusions of the imprinting mold onto the liquid photoresist layer; curing the liquid photoresist layer to form a solid photoresist layer; removing the imprinting mold from the solid photoresist layer to obtain the solid photoresist layer which is patterned, wherein the solid photoresist layer comprises a plurality of second protrusions and openings arranged in an array; forming a metal layer on upper surfaces of the second protrusions and in the openings; and peeling off the second protrusions and parts of the metal layer formed on the upper surfaces of the second protrusions, wherein remaining parts of the metal layer form a metal circuit.

Furthermore, under a condition of ultraviolet light, the liquid photoresist layer is cured for 60-100 s to form the solid photoresist layer.

Furthermore, the removing the imprinting mold from the solid photoresist layer comprises: removing the imprinting mold from the solid photoresist layer in a same horizontal direction as the side surface of the substrate to obtain the solid photoresist layer which is patterned.

Furthermore, the forming the metal layer on the upper surfaces of the second protrusions and in the openings comprises: depositing a metal material on the upper surfaces of the second protrusions and in the openings by physical vapor deposition to form the metal layer.

Furthermore, the first protrusions are shaped as isosceles trapezoids, and a shape of the first protrusions matches a shape of the openings.

Furthermore, a width of tops of the openings is less than a width of bottoms of the openings.

Furthermore, the width of the tops of the openings is 30-50 μm, and the width of the bottoms of the openings is 40-60 μm.

Furthermore, the metal layer is made of one or more of molybdenum, titanium, copper, and silver.

Furthermore, the metal circuit comprises a plurality of wires, a width of the wires is 40-60 μm, and a thickness of the wires is 3000-6000 Å.

In order to achieve the above purpose, the present disclosure further provides a micro-light emitting diode (micro-LED) device, comprising: a substrate, wherein a surface of the substrate defines a bonding area, and the bonding area is provided with a plurality of terminals arranged at intervals; and a metal circuit formed on a side surface of the substrate and comprising a plurality of wires, wherein the wires are connected to the terminals.

### BRIEF DESCRIPTION OF DRAWINGS

Specific implementation of the present disclosure will be described in detail below in conjunction with accompanying drawings to make technical solutions and beneficial effects of the present disclosure obvious.

FIG. 1 is a flowchart of a method for fabricating a micro-light emitting diode (micro-LED) device according to an embodiment of the present disclosure.

FIG. 2 is a schematic structural diagram of an imprinting mold according to an embodiment of the present disclosure.

FIG. 3 is a perspective view of a liquid photoresist layer formed on a side surface of a substrate according to an embodiment of the present disclosure.

FIG. 4 is a side view of the liquid photoresist layer formed on the side surface of the substrate according to an embodiment of the present disclosure.

FIG. 5 is a schematic structural diagram of the imprinting mold pressed on the liquid photoresist layer according to an embodiment of the present disclosure.

FIG. 6 is a schematic structural diagram of the imprinting mold removed from a solid photoresist layer according to an embodiment of the present disclosure.

FIG. 7 is a schematic structural diagram of a metal layer formed on upper surfaces of second protrusions and in openings according to an embodiment of the present disclosure.

FIG. 8 is a schematic diagram of a structure after the second protrusions are peeled off according to an embodiment of the present disclosure.

FIG. 9 is a schematic structural diagram of a metal circuit formed on the side surface of the substrate according to an embodiment of the present disclosure.

Reference numerals in the accompanying drawings comprise:
100: imprinting mold; 101: base plate; 102: first protrusion; 103: groove;
201: substrate; 201a: display area; 201b: bonding area; 202a: liquid photoresist layer; 202b: solid photoresist layer; 301: second protrusion; 302: opening; 303a: metal layer; 303b: metal circuit; 10: terminal; and 20: wires.

### DETAILED DESCRIPTION

Technical solutions in embodiments of the present disclosure will be clearly and completely described below in conjunction with accompanying drawings in the embodiments of the present disclosure. In a description of the present disclosure, it should be understood that terms “first” and “second” are merely used for descriptive purposes and should not to be construed as indicating or implying a relative importance or implicitly indicating a number of the indicated technical features. Therefore, the features defined by “first” and “second” may explicitly or implicitly comprise one or more of the features. In the description of the present disclosure, a term “a plurality of” means “two or more” unless otherwise specifically limited.

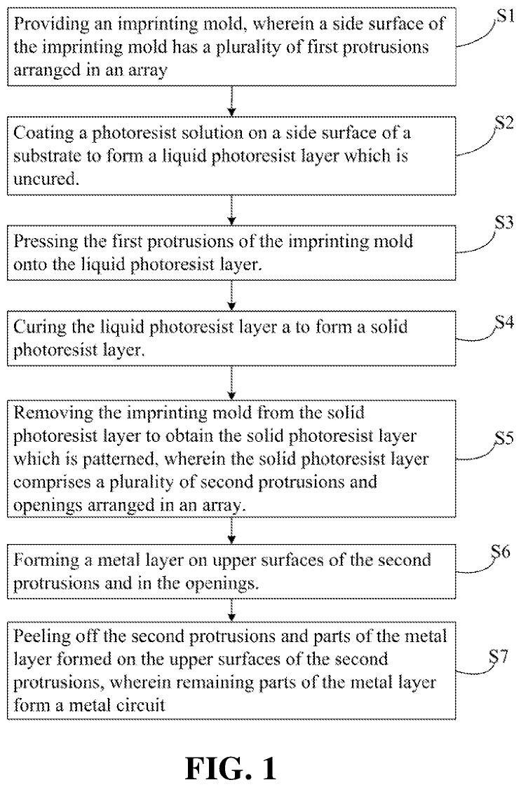

As shown in FIG. 1 to FIG. 9, the present disclosure provides a method for fabricating a micro-light emitting diode (micro-LED) device, which comprises the following steps S1 to S7.

S1: providing an imprinting mold 100, wherein a side surface of the imprinting mold 100 has a plurality of first protrusions 102 arranged in an array.

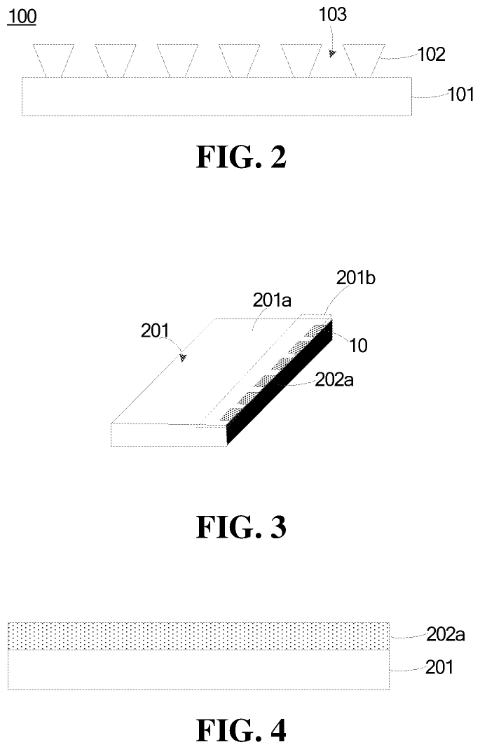

As shown in FIG. 2, the imprinting mold 100 comprises a base plate 101. An upper surface of the base plate 101 is provided with the first protrusions 102 arranged in an array. The first protrusions 102 are shaped as isosceles trapezoids, a length of their lower bases (a width of their tops away from the base plate 101) is 40-60 μm, and a length of their upper base (a width of their bottoms close to the base plate 101) is 30-50 μm. Two adjacent first protrusions 102 and the base plate 101 form a groove 103.

S2: coating a photoresist solution on a side surface of a substrate to form a liquid photoresist layer 202a which is uncured.

As shown in FIG. 3 and FIG. 4, a surface of the substrate 201 defines a display area 201a and a bonding area 201b. The bonding area 201b is provided with a plurality of terminals 10 arranged at intervals. The terminals 10 are formed synchronously with signal wires located in the display area 201a. That is, a manufacturing process of the terminals 10 is same as a manufacturing process of the signal wires located in the display area 201a. The terminals 10 and the signal wires located in the display area 201a may be made by laser, vapor deposition, or the like, which is not particularly limited herein.

In this embodiment, the photoresist solution is coated on the side surface of the substrate 201 close to the bonding area 201b to form the liquid photoresist layer 202a which is uncured.

S3: pressing the first protrusions 102 of the imprinting mold onto the liquid photoresist layer 202a.

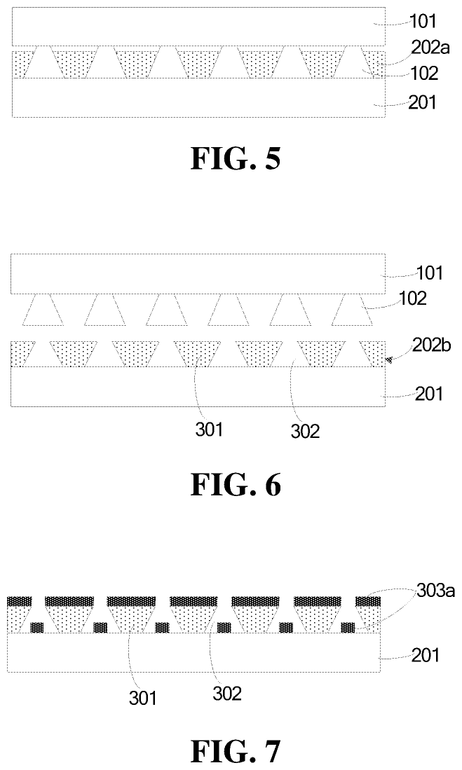

As shown in FIG. 5, the imprinting mold 100 is moved vertically so that the first protrusions 102 of the imprinting mold 100 are pressed on the liquid photoresist layer 202a.

S4: curing the liquid photoresist layer 202a to form a solid photoresist layer 202b.

Specifically, under a condition of ultraviolet light, the liquid photoresist layer 202a is cured for 60-100 s to form the solid photoresist layer 202b.

S5: removing the imprinting mold from the solid photoresist layer 202b to obtain the solid photoresist layer 202b which is patterned, wherein the solid photoresist layer 202b comprises a plurality of second protrusions 301 and openings 302 arranged in an array.

As shown in FIG. 6, the imprinting mold 100 is removed from the solid photoresist layer 202b in a same horizontal direction as the side surface of the substrate 201 to obtain the solid photoresist layer 202b which is patterned. The second protrusions 301 are shaped as isosceles trapezoids. A size of the openings 302 is same as a size of the first protrusions 102, which means that the first protrusions 102 of the imprinting mold 100 are completely imprinted on the liquid photoresist layer 202a, so that a pattern (i.e. the openings 302) of the subsequently molded solid photoresist layer 202b is same as a shape of the first protrusions 102. In this embodiment, a width of tops of the openings 302 is less than a width of bottoms of the openings 302. The width of the tops of the openings 302 is 30-50 μm. The width of the bottoms of the openings 302 is 40-60 μm. That is, each of the openings 302 has an undercut structure.

S6: forming a metal layer on upper surfaces of the second protrusions 301 and in the openings 302.

As shown in FIG. 7, depositing a metal material on the upper surfaces of the second protrusions 301 and in the openings 302 by physical vapor deposition to form the metal layer 303a. The metal layer 303a is made of one or more of molybdenum, titanium, copper, and silver. During a deposition process, the metal material is deposited from the tops of the openings 302 to the bottoms of the openings 302, that is, deposited on the surface of the substrate 201. Therefore, a width of parts of the metal layer 303a located in the openings 302 is equal to the width of the tops of the openings 302.

S7: peeling off the second protrusions 301 and parts of the metal layer 303a formed on the upper surfaces of the second protrusions 301, wherein remaining parts of the metal layer 303a form a metal circuit 303b.

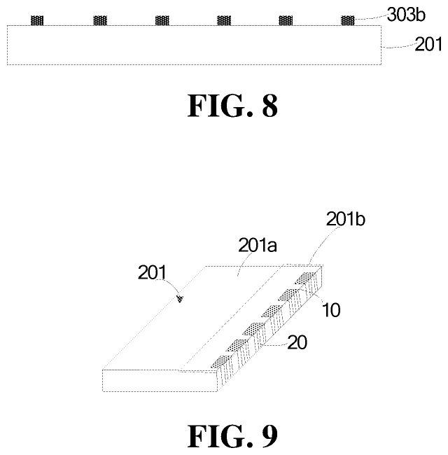

As shown in FIG. 8, the width of the parts of the metal layer 303a located in the openings 302 is equal to the width of the tops of the openings 302. Therefore, on a same horizontal line, a distance between an end of the metal layer 303a and a side of one adjacent second protrusion 301 is about 8 to 12 μm, preferably 10 μm. This can ensure that the parts of the metal layer 303a formed on the upper surfaces of the second protrusions 301 will not be connected to the parts of the metal layer 303a located in the openings 302. Therefore, in a process of peeling off the second protrusions 301, the parts of the metal layer 303a formed on the upper surfaces of the second protrusions 301 are peeled off together with the second protrusions 301. The parts of the metal layer 303a located in the openings 302 will not be peeled off or warped due to peeling of the second protrusions 301. In this embodiment, the remaining parts of the metal layer 303a (i.e. the parts of the metal layer 303a located in the openings 302) form the metal circuit 303b disposed on the side surface of the substrate 201. The metal circuit 303b comprises a plurality of wires 20. A width of the wires 20 is 40-60 μm, and a thickness of the wires 20 is 3000-6000 Å.

As shown in FIG. 9, the wires 20 of the metal circuit 303b is connected to the terminals 10 in the bonding area 201b, so as to realize signal connection between in-plane wires and out-of-plane wires of a display panel.

In the method for fabricating the micro-LED device provided by this embodiment, the metal circuit is formed on the side surface of the substrate by imprinting, so as to eliminate a complicated process of laser engraving on a side surface of the micro-LED device, thereby shortening a tact time and speeding up a production speed.

Please refer to FIG. 9, the present disclosure further provides a micro-light emitting diode (micro-LED) device, which is made by the aforementioned method and specifically comprises a substrate 201 and a metal circuit 303b.

Specifically, a surface of the substrate 201 defines a bonding area 201b. The bonding area 201b is provided with a plurality of terminals 10 arranged at intervals. The metal circuit 303b is formed on a side surface of the substrate 201. The metal circuit 303b comprises a plurality of wires 20. The wires 20 are connected to the terminals 10.

In the micro-LED device and the method for fabricating the same provided by this embodiment, the metal circuit is formed on the side surface of the substrate by imprinting, so as to eliminate a complicated process of laser engraving, thereby shortening a tact time and speeding up a production speed.

The micro-LED device and the method for fabricating the same provided by the embodiments of the present disclosure are described in detail above. The present disclosure uses specific examples to describe principles and embodiments of the present application. The above description of the embodiments is only for helping to understand the technical solutions of the present disclosure and its core ideas. It should be understood by those skilled in the art that they can modify the technical solutions recited in the foregoing embodiments, or replace some of technical features in the foregoing embodiments with equivalents. These modifications or replacements do not cause essence of corresponding technical solutions to depart from the scope of the technical solutions of the embodiments of the present disclosure.

What is claimed is:

1. A method for fabricating a micro-light emitting diode (micro-LED) device, comprising:
providing an imprinting mold, wherein a side surface of the imprinting mold has a plurality of first protrusions arranged in an array;
coating a photoresist solution on a side surface of a substrate to form a liquid photoresist layer which is uncured;
pressing the first protrusions of the imprinting mold onto the liquid photoresist layer;
curing the liquid photoresist layer to form a solid photoresist layer;
removing the imprinting mold from the solid photoresist layer to obtain the solid photoresist layer which is patterned, wherein the solid photoresist layer comprises a plurality of second protrusions and openings arranged in an array;
forming a metal layer on upper surfaces of the second protrusions and in the openings; and
peeling off the second protrusions and parts of the metal layer formed on the upper surfaces of the second protrusions, wherein remaining parts of the metal layer form a metal circuit.

2. The method for fabricating the micro-LED device according to claim 1, wherein under a condition of ultraviolet light, the liquid photoresist layer is cured for 60-100 s to form the solid photoresist layer.

3. The method for fabricating the micro-LED device according to claim 1, wherein the removing the imprinting mold from the solid photoresist layer comprises:
removing the imprinting mold from the solid photoresist layer in a same horizontal direction as the side surface of the substrate to obtain the solid photoresist layer which is patterned.

4. The method for fabricating the micro-LED device according to claim 1, wherein the forming the metal layer on the upper surfaces of the second protrusions and in the openings comprises:
depositing a metal material on the upper surfaces of the second protrusions and in the openings by physical vapor deposition to form the metal layer.

5. The method for fabricating the micro-LED device according to claim 1, wherein the first protrusions are shaped as isosceles trapezoids, and a shape of the first protrusions matches a shape of the openings.

6. The method for fabricating the micro-LED device according to claim 5, wherein a width of tops of the openings is less than a width of bottoms of the openings.

7. The method for fabricating the micro-LED device according to claim 6, wherein the width of the tops of the openings is 30-50 μm, and the width of the bottoms of the openings is 40-60 μm.

8. The method for fabricating the micro-LED device according to claim 1, wherein the metal layer is made of one or more of molybdenum, titanium, copper, and silver.

9. The method for fabricating the micro-LED device according to claim 1, wherein the metal circuit comprises a plurality of wires, a width of the wires is 40-60 μm, and a thickness of the wires is 3000-6000 Å.

10. A micro-light emitting diode (micro-LED) device, comprising:
a substrate, wherein a surface of the substrate defines a bonding area, and the bonding area is provided with a plurality of terminals arranged at intervals; and
a metal circuit formed on a side surface of the substrate and comprising a plurality of wires, wherein the wires are connected to the terminals.
